(19) United States
(12) Patent Application Publication
(10) Pub. No.: US 2026/0266891 A1
(43) Pub. Date: Sep. 10, 2026

(54) PATTERN TESTING METHOD, DEVICE, APPARATUS AND MEDIUM FOR SINGLE DIE

(71) Applicant: Shenzhen Rayson Technology Co, Ltd., Shenzhen (CN)

(72) Inventor: Zi Liu, Shenzhen (CN)

(21) Appl. No.: 19/403,885

(22) Filed: Nov. 30, 2025

(30) Foreign Application Priority Data
Jan. 20, 2025 (CN) 2025100822786

(51) Int. Cl. G01R 31/27

(52) U.S. Cl. CPC G01R 31/275

(57) ABSTRACT

This application discloses a pattern testing method and a device, an apparatus, and a medium for a single die. The method comprises: when the first capacity to be tested of a single first die to be tested in a wafer to be tested is greater than a preset capacity threshold, obtaining a current first parameter-passing file; the first parameter-passing file comprises: first algorithm selection information and a preset difference; updating the first algorithm selection information based on a first capacity difference between the first capacity to be tested and the preset capacity threshold and the preset difference to obtain second algorithm selection information and an updated second parameter-passing file; determining and starting a target pattern testing algorithm from multiple different candidate pattern testing algorithms according to the second algorithm selection information.

### TECHNICAL FIELD

This application pertains to the field of wafer testing technology, particularly to a pattern testing method, a pattern testing device, an electronic apparatus, and a medium for testing single die.

### BACKGROUND

Typically, during the chip manufacturing process, CP (Chip Probing, wafer) testing and FT (Final Test) testing are required. CP testing refers to the functional testing of chips performed after wafer fabrication. In this process, the exposed chip pins on an entire, undivided wafer are connected to a testing machine via probes, and a test pattern is executed to assess the chip's functionality. A memory wafer (Flash Wafer) usually contains several hundred dies. After wafer testing, the defective dies are marked. During die packaging, only the good dies are selected and packaged into finished products, while the defective dies, known as Ink Dies, are discarded. In the semiconductor industry, a die refers to an integrated circuit chip that has not undergone packaging, also known as a bare chip or wafer die.

Currently, during the testing of a single die, if the capacity to be tested of the single die exceeds a certain threshold, there is an issue of incomplete testing of that single die. Typically, the overall, underlying testing algorithm needs to be modified to complete the full testing of a single die with a capacity to be tested exceeding a certain threshold. However, adapting the overall, underlying testing algorithm to accommodate the capacity to be tested of a single die is challenging and inefficient, resulting in low single-die testing efficiency. Moreover, it is difficult to apply this approach to the variable batch testing scenarios commonly encountered in manufacturing.

### SUMMARY

This application aims to address at least one of the technical problems present in the prior art. To this end, the application proposes a pattern testing method, an pattern testing device, an electronic apparatus, and a medium for a single die, capable of matching different target pattern testing algorithms according to varying capacities to be tested of individual single dies for pattern testing, thereby improving the efficiency of single-die testing and enhancing testing universality.

In a first aspect, an embodiment of this application provides a pattern testing method for single dies, comprising:

identifying a first die to be tested from a wafer to be tested and determining the first capacity to be tested of the single first die;

acquiring a current first parameter-passing file when the first capacity to be tested exceeds a preset capacity threshold; wherein the first parameter-passing file comprises first algorithm selection information and a preset difference; the first algorithm selection information is binary data with all zeros, and the number of bits in the binary data is the same as the current first total number of candidate pattern testing algorithms;

updating the first algorithm selection information based on the first capacity difference between the first capacity to be tested and the preset capacity threshold, as well as the preset difference, to obtain second algorithm selection information and an updated second parameter-passing file comprising the second algorithm selection information;

running and parsing the second parameter-passing file to determine and initiate a target pattern testing algorithm from multiple different candidate pattern testing algorithms based on the second algorithm selection information; and

performing pattern testing on the first die to be tested zone-by-zone according to the second parameter-passing file and the target pattern testing algorithm to complete single-die testing.

According to some embodiments of this application, the updating the first algorithm selection information based on the first capacity difference between the first capacity to be tested and the preset capacity threshold, as well as the preset difference, to obtain second algorithm selection information and an updated second parameter-passing file comprising the second algorithm selection information, comprises:

subtracting the preset capacity threshold from the first capacity to be tested to obtain the first capacity difference;

dividing the first capacity difference by the preset difference to obtain a quotient;

rounding up the quotient to determine a bit position number;

modifying the low-level value corresponding to the target bit position in the first algorithm selection information indicated by the bit position number to a high-level value to obtain the updated second algorithm selection information;

generating an updated second parameter-passing file based on the second algorithm selection information.

According to some embodiments of this application, both the first parameter-passing file and the second parameter-passing file comprise an algorithm enabling signal.

The step of running and parsing the second parameter-passing file to determine and initiate a target pattern testing algorithm from multiple different candidate pattern testing algorithms based on the second algorithm selection information, comprises:

running and parsing the second parameter-passing file to obtain the algorithm enabling signal;

responding to the algorithm enabling signal to enable a pre-configured LK algorithm and determining multiple sorted candidate pattern testing algorithms from the LK algorithm; wherein different candidate pattern testing algorithms are configured based on different capacities to be tested;

responding to the low-level values in the second algorithm selection information to disable the candidate pattern testing algorithms at corresponding sorted positions;

responding to the high-level values in the second algorithm selection information to determine the candidate pattern testing algorithms at corresponding sorted positions as target pattern testing algorithms and initiating the target pattern testing algorithms.

According to some embodiments of this application, the method further comprises:

responding to an algorithm update instruction to add or delete candidate pattern testing algorithms in the LK algorithm;

determining the current second total number of candidate pattern testing algorithms in the LK algorithm;

modifying the first algorithm selection information based on the second total number to obtain updated first algorithm selection information; wherein the number of bits in the updated first algorithm selection information is determined by the second total number;

generating an updated first parameter-passing file based on the updated first algorithm selection information.

According to some embodiments of this application, the second parameter-passing file further comprises testing parameters.

The step of conducting pattern testing on the first die to be tested zone-by-zone according to the second parameter-passing file and the target pattern testing algorithm to complete single-die testing, comprises:

dividing the first die to be tested into a first test region and a second test region based on the preset capacity threshold; wherein the capacity to be tested in the first test region equals the preset capacity threshold; the capacity to be tested in the second test region equals the first capacity difference;

conducting first testing processing on the first test region based on a preset conventional testing mode;

acquiring the testing parameters from the second parameter-passing file and conducting second testing processing on the second test region according to the target pattern testing algorithm and the testing parameters;

completing the pattern testing when the first testing processing and the second testing processing are finished.

According to some embodiments of this application, the method further comprises:

determining a preset conventional pattern testing algorithm when the first capacity to be tested is less than or equal to the preset capacity threshold;

conducting pattern testing on the first die according to the preset conventional pattern testing algorithm to complete single-die testing.

According to some embodiments of this application, after conducting pattern testing on the first die to complete single-die testing, the method further comprises:

identifying a next second die to be tested from the wafer to be tested and determining the second capacity to be tested of the individual second die;

acquiring a current first parameter-passing file when the second capacity to be tested exceeds the preset capacity threshold; wherein the first parameter-passing file comprises first algorithm selection information and a preset difference; the first algorithm selection information is binary data with all zeros, and the number of bits in the binary data is the same as the current first total number of candidate pattern testing algorithms;

updating the first algorithm selection information based on the second capacity difference between the second capacity to be tested and the preset capacity threshold, as well as the preset difference, to obtain third algorithm selection information and an updated third parameter-passing file comprising the third algorithm selection information;

running and parsing the third parameter-passing file to determine and initiate a target pattern testing algorithm from multiple candidate pattern testing algorithms based on the third algorithm selection information;

conducting pattern testing on the second die to be tested zone-by-zone according to the third parameter-passing file and the target pattern testing algorithm to complete single-die testing;

continuing until pattern testing is completed for all dies to be tested on the wafer, and ending wafer testing.

In a second aspect, an embodiment of this application provides a pattern testing device for single dies, comprising at least one processor and a memory for communication connection with the at least one processor; the memory stores instructions executable by the at least one processor, the instructions being executed by the at least one processor to enable the at least one processor to perform the pattern testing method for single dies as described in any embodiment of the first aspect.

In a third aspect, an embodiment of this application provides an electronic apparatus, comprising the pattern testing device for single dies as described in the embodiment of the second aspect.

In a fourth aspect, an embodiment of this application provides a computer-readable storage medium, wherein the computer-readable storage medium stores computer-executable instructions, the computer-executable instructions being configured to cause a computer to execute the pattern testing method for single dies as described in any embodiment of the first aspect.

The embodiments of this application comprise: by utilizing a pattern testing device for single dies, first, a first die to be tested is identified from a wafer to be tested, and the first capacity to be tested of the individual first die is determined; second, when the first capacity to be tested exceeds a preset capacity threshold, a current first parameter-passing file is acquired; wherein the first parameter-passing file comprises first algorithm selection information and a preset difference; the first algorithm selection information is binary data with all zeros, and the number of bits in the binary data is the same as the current first total number of candidate pattern testing algorithms; then, the first algorithm selection information is updated based on the first capacity difference between the first capacity to be tested and the preset capacity threshold, as well as the preset difference, to obtain second algorithm selection information and an updated second parameter-passing file comprising the second algorithm selection information; next, the second parameter-passing file is run and parsed to determine and initiate a target pattern testing algorithm from multiple different candidate pattern testing algorithms based on the second algorithm selection information; thus, there is no need to rewrite the underlying testing algorithm; instead, different target pattern testing algorithms can be quickly and directly matched and called according to varying capacities to be tested of individual single dies, laying a foundation for conducting pattern testing and facilitating an improvement in the efficiency of single-die testing; finally, pattern testing is conducted on the first die to be tested zone-by-zone according to the second parameter-passing file and the target pattern testing algorithm to complete single-die testing; thereby it can improve the efficiency of single-die testing and enhance testing universality. That is to say, the embodiments of this application are capable of matching different target pattern testing algorithms according to varying capacities to be tested of individual single dies for pattern testing, improving the efficiency of single-die testing, and enhancing testing universality.

### BRIEF DESCRIPTION OF THE DRAWINGS

FIG. 1 is a structural schematic diagram of a Pattern testing system for a single die provided in an embodiment of the present application.

FIG. 2 is a flowchart showing the steps of a Pattern testing method for a single die provided in an embodiment of the present application.

FIG. 3 is a specific schematic diagram for determining a target Pattern testing algorithm provided in an embodiment of the present application.

FIG. 4 is a detailed flowchart of step S140 in FIG. 2.

FIG. 5 is a hardware structural schematic diagram of a Pattern testing device for a single die provided in an embodiment of the present application..

### DETAILED DESCRIPTION

In order to make the objectives, technical solutions, and advantages of this application clearer, the following provides a further detailed description of this application with reference to the accompanying drawings and embodiments.

It should be noted that although logical sequences are illustrated in the flowcharts in the description of this application, in certain cases, the steps shown or described may be performed in a sequence different from that in the flowcharts. In the description of this application, the term "several" means one or more, and "multiple" means two or more. The terms "first" and "second" are used solely for the purpose of distinguishing technical features and should not be interpreted as indicating or implying relative importance or implicitly specifying the quantity or sequential relationship of the indicated technical features.

Unless otherwise defined, all technical and scientific terms used herein have the same meanings as commonly understood by technicians in the technical field to which this application pertains. The terms used herein are solely for the purpose of describing the embodiments of this application and are not intended to limit it.

This application discloses a Pattern testing method for a single die, a Pattern testing device for a single die, an electronic apparatus, and a computer-readable storage medium, which relate to the field of wafer testing technology. The method comprises the following steps: obtaining the current first parameter-passing file when the first test capacity of a single first die to be tested on a wafer under test is greater than a preset capacity threshold; the first parameter-passing file comprises: first algorithm selection information and a preset difference value. Based on the first capacity difference between the first test capacity and the preset capacity threshold, as well as the preset difference value, update the first algorithm selection information to obtain second algorithm selection information and an updated second parameter-passing file. A target Pattern testing algorithm is determined and initiated from multiple different candidate Pattern testing algorithms according to the second algorithm selection information. A Pattern test is performed on the first die in a region-by-region manner based on the second parameter-passing file and the target Pattern testing algorithm, thereby completing the single-die testing. This approach can improve the efficiency of single-die testing and enhance the universality of testing.

The following provides a further elaboration on the embodiments of this application with reference to the accompanying drawings.

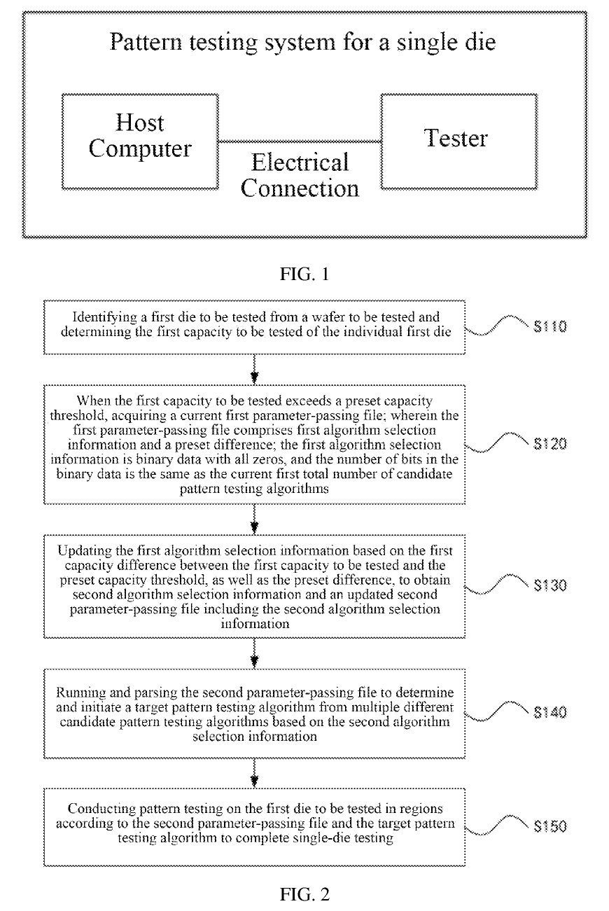

As shown in FIG. 1, the Pattern testing system for a single die comprises a host computer and a testing machine. The host computer is electrically connected to the testing machine. The testing machine is configured to load the wafer under test, while the host computer is configured to run the testing software. The host computer and the testing machine cooperate with each other to execute the Pattern testing method for a single die provided in the embodiments of this application. This system can match different target Pattern testing algorithms according to the varying test capacities of different single dies to perform Pattern tests on single dies, thereby improving the efficiency of single-die testing.

It can be understood by those skilled in the art that the system architecture illustrated in the figures does not constitute a limitation on the embodiments of this application. The system may comprise more or fewer components than those shown, or some components may be combined, or different component arrangements may be employed.

The system embodiments described above are merely illustrative. The units described as separate components may or may not be physically separated, meaning they can be located in one place or distributed across multiple network units. Some or all of the modules can be selected according to actual needs to achieve the objectives of the solutions in this embodiment.

It can be understood by those skilled in the art that the system architecture and application scenarios described in the embodiments of this application are intended to provide a clearer explanation of the technical solutions presented in this application. They do not constitute limitations on the technical solutions provided in the embodiments of this application. Those skilled in the art will recognize that as system architectures evolve and new application scenarios emerge, the technical solutions provided in the embodiments of this application are equally applicable to similar technical problems.

Based on the aforementioned system architecture, the following presents various embodiments of the Pattern testing method for a single die in this application.

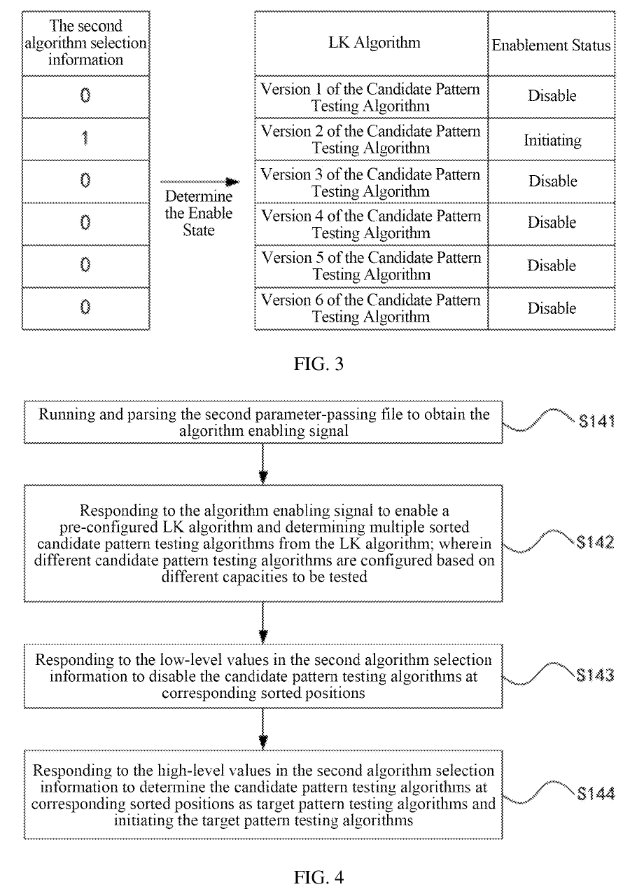

In the first aspect, as shown in FIG. 2, the Pattern testing method for a single die may comprise, but is not limited to, steps S110 to S150:

Step S110: identifying the first die to be tested from the wafer under test and determining the first test capacity of the single first die;

Step S120: obtaining the current first parameter-passing file when the first test capacity is greater than a preset capacity threshold; wherein the first parameter-passing file comprises: first algorithm selection information and a preset difference value; the first algorithm selection information is binary data consisting entirely of zeros, with the number of bits equal to the current first total number of candidate Pattern testing algorithms;

Step S130: updating the first algorithm selection information to obtain second algorithm selection information and an updated second parameter-passing file that comprises the second algorithm selection information based on the first capacity difference between the first test capacity and the preset capacity threshold, as well as the preset difference value;

Step S140: the second parameter-passing file is run and parsed to determine and initiate a target Pattern testing algorithm from multiple different candidate Pattern testing algorithms based on the second algorithm selection information;

Step S150: a Pattern test is performed on the first die to be tested in a region-by-region manner based on the second parameter-passing file and the target Pattern testing algorithm, thereby completing the single-die testing.

Further elaboration on Step S110: identifying the first die to be tested from the wafer under test specifically involves: for the dies to be tested, the host computer sending a single Die testing instruction to the testing machine via a serial port, the testing machine's GPIO controlling the selection chip to establish signal connections with the dies to be tested; for dies that do not require testing, no signal connections are made; thus, identifying the first die to be tested from the wafer under test.

It can be understood that a Die product consists of multiple blocks. Determining the first test capacity of a single first die specifically involves: reading the number of blocks and determining the first test capacity of the single first die based on the number of blocks and the capacity per block.

Specifically, the preset capacity threshold is 3GB, but it can also be set to other values based on actual testing conditions. Therefore, this application does not impose specific restrictions on the value of the preset capacity threshold.

It can be understood that the first parameter-passing file comprises: first algorithm selection information, test parameters, a preset difference value, and an algorithm enable signal. The test parameters, preset difference value, and first algorithm selection information can be pre-configured separately through a configuration interface provided by the host computer. Additionally, the current first algorithm selection information can also be updated based on the current second total number of candidate Pattern testing algorithms in the LK algorithm and the previous first algorithm selection information when candidate Pattern testing algorithms are added or removed in the LK algorithm. The algorithm enable signal is configured to enable the pre-configured LK algorithm.

Specifically, the first algorithm selection information is binary data consisting entirely of zeros, with the number of bits equal to the current first total number of candidate Pattern testing algorithms. For example, when the current first total number of candidate Pattern testing algorithms is 6, the first algorithm selection information is: 000000.

Specifically, the preset difference value can be 0.5, 1.5, 2, 3, etc. This application does not impose specific restrictions on the value of the preset difference value.

Specifically, the test parameters comprise, but are not limited to: test start address, test background data, and test capacity. The test start address is configured to determine the starting position for testing within the die to be tested, while the test capacity is configured in conjunction with the test start address to determine the ending address for testing. The test background data is used in the read-write verification process performed on the die to be tested. The read-write verification process involves: inverting the background data to obtain write data, writing the write data to the storage space of the die to be tested, reading the write data to obtain read-back data, and verifying whether the write data and read-back data are consistent. If they are consistent, it is judged that there are no errors in the storage space of the die. If they are inconsistent, it is judged that there are errors in the storage space of the die, and error information is recorded.

It can be understood that the difference between the first parameter-passing file and the second parameter-passing file lies in the fact that the first algorithm selection information and the second algorithm selection information are different, while the other test parameters, preset difference value, and algorithm enable signal remain the same.

Specifically, the different candidate Pattern testing algorithms are configured based on different test capacities.

It can be understood that the Pattern testing method provided in this application is implemented during the preloader stage.

Through steps S110 to S150, this application utilizes a Pattern testing device for a single die to first identify the first die to be tested from the wafer under test and determine the first test capacity of the single first die. Subsequently, when the first test capacity is greater than the preset capacity threshold, the current first parameter-passing file is obtained. The first parameter-passing file comprises: first algorithm selection information and a preset difference value. The first algorithm selection information is binary data consisting entirely of zeros, with the number of bits equal to the current first total number of candidate Pattern testing algorithms. Then, based on the first capacity difference between the first test capacity and the preset capacity threshold, as well as the preset difference value, the first algorithm selection information is updated to obtain second algorithm selection information and an updated second parameter-passing file that comprises the second algorithm selection information. Next, the second parameter-passing file is parsed and run to determine and initiate a target Pattern testing algorithm from multiple different candidate Pattern testing algorithms based on the second algorithm selection information. This approach eliminates the need to rewrite the underlying testing algorithm and instead allows for the rapid and direct matching and invocation of different target Pattern testing algorithms based on different test capacities of single dies, laying the foundation for performing Pattern tests and improving the efficiency of single-die testing. Finally, a Pattern test is performed on the first die to be tested in a region-by-region manner based on the second parameter-passing file and the target Pattern testing algorithm, thereby completing the single-die testing. This approach enhances the efficiency of single-die testing and increases the universality of testing. In other words, this application can match different target Pattern testing algorithms based on different test capacities of single dies to perform Pattern tests, improving the efficiency of single-die testing and increasing the universality of testing.

According to some embodiments of this application, further elaboration on Step S130 is provided. Step S130, which involves updating the first algorithm selection information based on the first capacity difference between the first test capacity and the preset capacity threshold, as well as the preset difference value, to obtain second algorithm selection information and an updated second parameter-passing file that comprises the second algorithm selection information, comprises, but is not limited to, steps S131 to S135:

Step S131: subtracting the preset capacity threshold from the first test capacity to obtain the first capacity difference;

Step S132: dividing the first capacity difference by the preset difference value to obtain a quotient;

Step S133: rounding up the quotient to obtain an integer, which is then designated as the bit position number;

Step S134: modifying the low-level value corresponding to the target bit position in the first algorithm selection information, as indicated by the bit position number, to a high-level value, thereby obtaining the updated second algorithm selection information;

Step S135: generate an updated second parameter-passing file based on the second algorithm selection information.

Specifically, the high-level value is 1, and the low-level value is 0.

An example is provided to illustrate the specific process of steps S131 to S135. When the first algorithm selection information is 000000, the first test capacity is 9.5GB, the preset capacity threshold is 3GB, and the preset difference value is 5GB, the first capacity difference is 9.5- 3 = 6.5 (GB). Dividing the first capacity difference of 6.5GB by the preset difference value of 5GB yields a quotient of 1.3. Rounding up the quotient of 1.3 yields a bit position number of 2. Correspondingly, based on the bit position number of 2, the second bit position in the first algorithm selection information is designated as the target bit position. The low-level value corresponding to the target bit position is modified to a high-level value, resulting in the updated second algorithm selection information of 010000.

Through steps S131 to S135, the first algorithm selection information is updated based on the test capacity of the single die to obtain the second algorithm selection information, facilitating the subsequent rapid and direct matching and invocation of different target Pattern testing algorithms based on the second algorithm selection information.

According to some embodiments of this application, both the first parameter-passing file and the second parameter-passing file comprise an algorithm enable signal.Combining with FIG. 4, further elaboration on Step S140 is provided. Step S140, which involves parsing and running the second parameter-passing file to determine and initiate a target Pattern testing algorithm from multiple different candidate Pattern testing algorithms based on the second algorithm selection information, comprises, but is not limited to, steps S141 to S144:

Step S141: parsing and running the second parameter-passing file to obtain the algorithm enable signal;

Step S142: enabling the pre-configured LK algorithm and determine multiple sorted candidate Pattern testing algorithms from the LK algorithm in response to the algorithm enable signal, wherein, the different candidate Pattern testing algorithms are configured based on different test capacities;

Step S143: disabling the candidate Pattern testing algorithms at the corresponding sorted positions in response to the low-level values in the second algorithm selection information;

Step S144: determining the candidate Pattern testing algorithms at the corresponding sorted positions as the target Pattern testing algorithms and initiate them in response to the high-level values in the second algorithm selection information,.

It can be understood that LK (Little Kernel) refers to a microkernel. The LK algorithm is pre-configured and comprises multiple candidate Pattern testing algorithms. The different candidate Pattern testing algorithms are configured based on different test capacities and are sorted in ascending order of test capacity. For example, candidate Pattern testing algorithm 1 corresponds to a test capacity range of 3GB to 8GB, candidate Pattern testing algorithm 2 corresponds to a test capacity range of 8GB to 13GB, and so on.

For example, as shown in FIG. 3, the enable status of each candidate Pattern testing algorithm is determined based on the second algorithm selection information. Specifically, when the updated second algorithm selection information is 010000, the candidate Pattern testing algorithm 1 and candidate Pattern testing algorithms 3 to 6 in the LK algorithm are disabled accordingly; the candidate Pattern testing algorithm 2 is determined as the target Pattern testing algorithm, and the target Pattern testing algorithm is initiated.

Through steps S141 to S144, it is not necessary to rewrite the underlying testing algorithms. Instead, different target Pattern testing algorithms can be quickly and directly matched and called according to different single-die test capacities, laying the foundation for Pattern testing and facilitating the improvement of single-die testing efficiency.

According to some embodiments of this application, the second parameter passing file also comprises: test parameters;

step S150 is further elaborated as follows: step S150: performing Pattern testing on the first die to be tested in different regions to complete single-die testing according to the second parameter passing file and the target Pattern testing algorithm, comprises but not limited to steps S151 to S154:

Step S151: dividing the first die to be tested into a first test region and a second test region according to a preset capacity threshold, wherein the test capacity of the first test region is equal to the preset capacity threshold, the test capacity of the second test region is equal to the first capacity difference;

Step S152: performing the first test processing on the first test region based on a preset normal testing mode;

Step S153: obtaining test parameters from the second parameter passing file, and performing the second test processing on the second test region according to the target Pattern testing algorithm and the test parameters;

Step S154: completing the Pattern testing is completed when the first test processing and the second test processing are completed.

In one embodiment, when performing the first test processing in step S152, steps S120 to S140 can be carried out simultaneously to determine the target Pattern testing algorithm. When the first test processing is completed, the second test processing in step S153 is then executed, thereby improving the testing efficiency of single-die testing.

In one embodiment, after performing steps S120 to S140 to determine the target Pattern testing algorithm, steps S152 to S153 can also be executed simultaneously to improve the testing efficiency of single-die testing.

Through steps S151 to S154, single-die testing is completed on the first die in different regions, improving the testing efficiency of single-die testing.

According to some embodiments of this application, after step S110, the Pattern testing method for a single die also comprises: determining a preset normal Pattern testing algorithm when the first test capacity is less than or equal to the preset capacity threshold; performing Pattern testing on the first die to complete single-die testing according to the preset normal Pattern testing algorithm. In this way, for the first die with a first test capacity less than or equal to the preset capacity threshold, there is no need to call the target Pattern testing algorithm based on the second parameter passing file. Instead, the existing preset normal Pattern testing algorithm is directly used for Pattern testing to complete single-die testing, thus facilitating the improvement of testing efficiency.

According to some embodiments of this application, the Pattern testing method for a single die also comprises but is not limited to steps S210 to S240:

Step S210: adding or deleting candidate Pattern testing algorithms in the LK algorithm in response to an algorithm update instruction.

Step S220: determining the second total number of candidate Pattern testing algorithms in the current LK algorithm;

Step S230: modifying the first algorithm selection information according to the second total number to obtain updated first algorithm selection information, wherein the number of bits of the updated first algorithm selection information is determined by the second total number;

Step S240: generate an updated first parameter passing file according to the updated first algorithm selection information.

It can be understood that the LK algorithm can be modified, and the candidate Pattern testing algorithms can be custom-configured, updated, and modified. Therefore, testers can update the LK algorithm through the configuration interface provided by the host computer by using the following operations: adding or deleting candidate Pattern testing algorithms, adjusting the order among candidate Pattern testing algorithms, or modifying the specific content of Pattern testing algorithms.

It can be understood that when the candidate Pattern testing algorithms in the LK algorithm are updated, it is necessary to re-count the second total number of candidate Pattern testing algorithms in the current LK algorithm and then modify the first algorithm selection information of the first parameter passing file as a benchmark. This facilitates the subsequent calling of new candidate Pattern testing algorithms and the new LK algorithm.

The Pattern testing algorithm is further explained. In wafer testing, tests such as leakage current testing and operating current testing are involved. These tests are mainly completed by performing multiple read and write operations on the test object. The basic statement formats of the above two operations are both: [command] + [address] + [data]. Wherein [command] is a read or write instruction; [address] is the addressing information that determines the location of the minimum storage unit in the storage space of the test object; [data] is the content information to be stored in the corresponding address of the Flash. Currently, in CP (Chip Probing wafer testing) testing, vector templates Pattern are usually configured to simplify testing operations. The following steps are comprised: writing pre-operations (such as powering on relevant pins) in the Pattern testing algorithm, writing "command + address + data" in the Pattern, and finally running the Pattern testing algorithm to complete the read or write operation on the test object. Before testing, multiple candidate Pattern testing algorithms are written and saved in the internal storage space of the tester for quick reading. The Pattern testing algorithm comprises pre-operations, commands, addresses, and data. At this time, the address in the Pattern testing algorithm is any Flash address in the die to be tested, and the data is generally set to 0. This application configures different candidate Pattern testing algorithms based on different test capacities.

Through steps S210 to S240, in the case of an update to the LK algorithm, the first algorithm selection information and the first parameter passing file are updated in a timely manner; thus providing reliable guarantees for subsequently matching different target Pattern testing algorithms according to different single-die test capacities.

According to some embodiments of this application, after performing Pattern testing on the first die to complete single-die testing, the method also comprises but is not limited to steps S310 to S360:

Step S310: determining the next second die to be tested from the wafer to be tested, and determining the second test capacity of a single second die;

Step S320: obtaining the current first parameter passing file when the second test capacity is greater than the preset capacity threshold; wherein the first parameter passing file comprises: first algorithm selection information and a preset difference; the first algorithm selection information is binary data with all bits being 0, and the number of bits of the binary data is the same as the current first total number of candidate Pattern testing algorithms;

Step S330: updating the first algorithm selection information to obtain third algorithm selection information and an updated third parameter passing file comprising the third algorithm selection information, according to the second capacity difference between the second test capacity and the preset capacity threshold and the preset difference .

Step S340: running and parsing the third parameter passing file, and determining and initiating a target Pattern testing algorithm from multiple candidate Pattern testing algorithms according to the third algorithm selection information;

Step S350: performing Pattern testing on the second die to be tested in different regions to complete single-die testing according to the third parameter passing file and the target Pattern testing algorithm;

Step S360: ending the wafer testing until Pattern testing is completed for all dies to be tested on the wafer to be tested.

It can be understood that a wafer to be tested comprises multiple dies to be tested, and each die to be tested needs to be tested. Therefore, after performing steps S110 to S150, the next second die to be tested is determined in sequence, and steps S310 to S350 are executed to complete single-die testing on the second die. When it is judged that the currently tested second die is not the last die to be tested on the wafer to be tested, steps S310 to S350 are automatically repeated to complete single-die testing on the next die to be tested; until the testing of the last die to be tested on the wafer to be tested is completed, it is judged that Pattern testing is completed for all dies to be tested on the wafer to be tested, and the wafer testing is ended; automated testing of a wafer to be tested is achieved, improving the overall efficiency of wafer testing.

It can be understood that Pattern testing is carried out based on the target Pattern testing algorithm, and different target Pattern testing algorithms result in different specific Pattern testing. This application does not impose specific restrictions on each candidate Pattern testing algorithm here; they can be custom-configured by testers according to requirements.

Through steps S310 to S360, all dies to be tested on the wafer to be tested are automatically tested, which is conducive to improving the overall efficiency of wafer testing.

In one embodiment, when at least two wafers to be tested are loaded on the tester, after the host computer completes wafer testing on one wafer to be tested, it continues to automatically test the next wafer to be tested; all test results are recorded in the host computer; to facilitate testers to view the test situations.

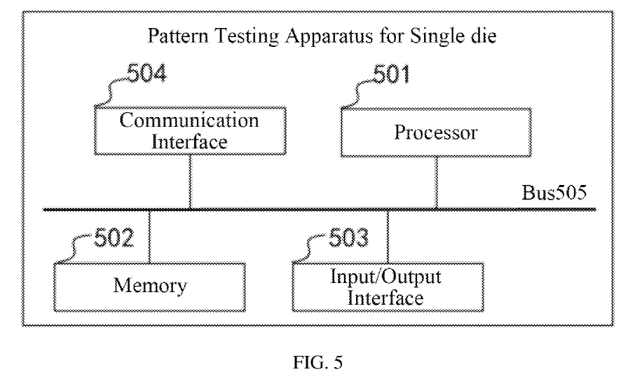

As shown in FIG. 5, which is a hardware structural schematic diagram of a Pattern testing device for a single die provided in one embodiment of this application. The present disclosure also provides a Pattern testing device for a single die, comprising:

a processor 501, which can be implemented using a general-purpose Central Processing Unit (CPU), a microprocessor, an Application Specific Integrated Circuit (ASIC), or one or more integrated circuits, etc; wherein the processor 501 is configured to execute relevant programs to implement the technical solutions provided in the embodiments of this application;

a memory 502, which can be implemented in the form of Read Only Memory (ROM), static storage devices, dynamic storage devices, or Random Access Memory (RAM), etc; wherein the memory 502 can store the operating system and other application programs; when implementing the technical solutions provided in the embodiments of this specification through software or firmware, the relevant program codes are stored in the memory 502, and the processor 501 is configured to invoke and execute the Pattern testing method for a single die provided in the embodiments of this application;

an input/output interface 503, configured to input and output for information;.

a communication interface 504, configured to communicate and interacte between this device and other devices, wherein communication can be achieved through wired means (such as USB, network cables, etc.) or wireless means (such as mobile networks, WIFI, Bluetooth, etc.);

a bus 505, which transmits information among various components of the device (such as the processor 501, memory 502, input/output interface 503, and communication interface 504).

The processor 501, memory 502, input/output interface 503, and communication interface 504 are interconnected within the device through the bus 505 for communication.

The embodiments of this application also provide an electronic apparatus, which comprises the aforementioned Pattern testing device for a single die.

The embodiments of this application also provide a storage medium, which is a computer-readable storage medium. This storage medium stores a computer program, and when executed by a processor, the computer program implements the aforementioned Pattern testing method for a single die.

As a non-transitory computer-readable storage medium, the memory can be configured to store non-transitory software programs and non-transitory computer-executable programs. In addition, the memory may comprise high-speed random-access memory and may also comprise non-transitory memory, such as at least one magnetic disk storage device, flash memory device, or other non-transitory solid-state storage devices. In some implementations, the memory may optionally comprise memory located remotely from the processor, and these remote memories can be connected to the processor via a network. Examples of such networks comprise, but are not limited to, the Internet, intranets, local area networks, mobile communication networks, and combinations thereof. The device embodiments described above are merely illustrative. The units described as separate components may or may not be physically separate, and they may be located in one place or distributed across multiple network units. Depending on actual needs, some or all of the modules can be selected to achieve the objectives of the embodiments of this solution.

Ordinary technicians in the field can understand that all or some of the steps and systems in the publicly disclosed methods above can be implemented as software, firmware, hardware, and appropriate combinations thereof. Some or all physical components can be implemented as software executed by a processor, such as a central processor, digital signal processor, or microprocessor, or as hardware, or as integrated circuits, such as application-specific integrated circuits. Such software can be distributed on computer-readable media, which can comprise computer storage media (or non-transitory media) and communication media (or transitory media). As is well known to ordinary technicians in the field, the term computer storage media comprises volatile and non-volatile, removable and non-removable media implemented in any method or technology for storing information (such as computer-readable instructions, data structures, program modules, or other data). Computer storage media comprise, but are not limited to, RAM, ROM, EEPROM, flash memory, or other memory technologies, CD-ROMs, digital versatile discs (DVDs), or other optical disc storage, magnetic cassettes, magnetic tapes, magnetic disk storage, or other magnetic storage devices, or any other media that can be configured to store the desired information and can be accessed by a computer. In addition, as is well known to ordinary technicians in the field, communication media typically comprise computer-readable instructions, data structures, program modules, or other data in modulated data signals, such as carrier waves or other transmission mechanisms, and can comprise any information delivery media.

The above provides a detailed description of the preferred embodiments of this application. However, this application is not limited to the above-mentioned implementations. Technicians familiar with the field can make various equivalent modifications or substitutions without departing from the spirit of this application. These equivalent modifications or substitutions are all comprised within the scope defined by this application.

1. A pattern testing method for a single die, comprising:
S110: determining a first die to be tested from a wafer to be tested, and determining a first capacity to be tested for the single first die;
S120: obtaining a current first parameter-passing file when the first capacity to be tested is greater than a preset capacity threshold; wherein the first parameter-passing file comprises: first algorithm selection information and a preset difference; the first algorithm selection information is binary data with all zeros, and a number of bits of the binary data is the same as a current first total number of candidate pattern testing algorithms;
S130: updating the first algorithm selection information based on, a first capacity difference between the first capacity to be tested and the preset capacity threshold, and the preset difference to obtain second algorithm selection information and an updated second parameter-passing file comprising the second algorithm selection information;
S140: running and parsing the second parameter-passing file, and determining and starting a target pattern testing algorithm from multiple different candidate pattern testing algorithms according to the second algorithm selection information;
S150: performing pattern testing on the first die to be tested zone-by-zone based on the second parameter-passing file and the target pattern testing algorithm to complete single-die testing.

2. The pattern testing method for the single die according to claim 1, wherein the updating the first algorithm selection information based on, the first capacity difference between the first capacity to be tested and the preset capacity threshold, and the preset difference to obtain the second algorithm selection information and the updated second parameter-passing file comprising the second algorithm selection information, comprises:
subtracting the preset capacity threshold from the first capacity to be tested to obtain the first capacity difference;
dividing the first capacity difference by the preset difference to obtain a quotient;
rounding up the quotient to obtain an integer, and determining the integer as a bit position number;
modifying a low-level value at a target bit position in the first algorithm selection information indicated by the bit position number to a high-level value to obtain an updated second algorithm selection information; and
generating the updated second parameter-passing file according to the second algorithm selection information.

3. The pattern testing method for the single die according to claim 2, wherein both the first parameter-passing file and the second parameter-passing file comprise an algorithm enable signal;
the running and parsing the second parameter-passing file, and determining and starting the target pattern testing algorithm from multiple different candidate pattern testing algorithms according to the second algorithm selection information, comprises:
running and parsing the second parameter-passing file to obtain the algorithm enable signal;
enabling a pre-configured LK algorithm in response to the algorithm enable signal, and determining multiple ranked candidate pattern testing algorithms from the LK algorithm; wherein different candidate pattern testing algorithms are obtained based on different capacity configurations to be tested;
disabling a candidate pattern testing algorithm at a corresponding ranked position in response to a low-level value in the second algorithm selection information;
determining a candidate pattern testing algorithm at a corresponding ranked position as a target pattern testing algorithm in response to a high-level value in the second algorithm selection information, and starting the target pattern testing algorithm.

4. The pattern testing method for the single die according to claim 3, wherein the method further comprises:
adding or removing candidate pattern testing algorithms in the LK algorithm in response to an algorithm update instruction ;
determining a second total number of candidate pattern testing algorithms in the current LK algorithm;
modifying the first algorithm selection information according to the second total number to obtain updated first algorithm selection information; wherein the number of bits of the updated first algorithm selection information is determined by the second total number; and
generating the updated first parameter-passing file according to the updated first algorithm selection information.

5. The pattern testing method for the single die according to claim 1, wherein the second parameter-passing file further comprises testing parameters;
the performing pattern testing on the first die to be tested zone-by-zone based on the second parameter-passing file and the target pattern testing algorithm to complete single-die testing, comprises:
dividing the first die to be tested into a first test region and a second test region according to the preset capacity threshold; wherein the capacity to be tested in the first test region is equal to the preset capacity threshold;
the capacity to be tested in the second test region is equal to the first capacity difference;
performing a first test on the first test region based on a preset normal testing mode; obtaining the testing parameters from the second parameter-passing file, and performing a second test on the second test region according to the target pattern testing algorithm and the testing parameters; and
completing the pattern testing when the first test and the second test are completed.

6. The pattern testing method for a single die according to claim 1, wherein the method further comprises:
determining a preset normal pattern testing algorithm when the first capacity to be tested is less than or equal to the preset capacity threshold ; and
performing pattern testing on the first die according to the preset normal pattern testing algorithm to complete single-die testing.

7. The pattern testing method for the single die according to claim 1, wherein after performing pattern testing on the first die to complete single-die testing, further comprising:
determining a next second die to be tested from the wafer to be tested, and determining a second capacity to be tested for the single second die;
when the second capacity to be tested is greater than the preset capacity threshold, obtaining the current first parameter-passing file; wherein the first parameter-passing file comprises: first algorithm selection information and a preset difference; the first algorithm selection information is binary data with all zeros, and the number of bits of the binary data is the same as the current first total number of candidate pattern testing algorithms;
updating the first algorithm selection information based on, a second capacity difference between the second capacity to be tested and the preset capacity threshold, and the preset difference to obtain third algorithm selection information and an updated third parameter-passing file comprising the third algorithm selection information;
running and parsing the third parameter-passing file, and determining and starting a target pattern testing algorithm from multiple candidate pattern testing algorithms according to the third algorithm selection information;
performing pattern testing on the second die to be tested zone-by-zone based on the third parameter-passing file and the target pattern testing algorithm to complete single-die testing;
ending wafer testing until pattern testing on all dies to be tested in the wafer to be tested is completed.

8. A pattern testing device for a single die, comprising at least one processor and a memory for communication connection with the at least one processor; the memory stores instructions executable by the at least one processor, and the instructions are executed by the at least one processor to enable the at least one processor to perform the pattern testing method for the single die according to claim 1.

9. An electronic apparatus, comprising the pattern testing device for the single die according to claim 8.
